(19) United States
(12) Patent Application Publication
(10) Pub. No.: US 2017/0329357 A1
(43) Pub. Date: Nov. 16, 2017

(54) SYSTEM AND METHOD FOR IDENTIFYING DRIVERS OF CLIMATE CONTROL SYSTEM DEMAND

(71) Applicant: Palo Alto Research Center Incorporated, Palo Alto, CA (US)

(72) Inventors: Francisco E. Torres, San Jose, CA (US); Sylvia J. Smullin, Menlo Park, CA (US)

(21) Appl. No.: 15/155,467

(22) Filed: May 16, 2016

(51) Int. Cl. G05D 23/19; G01R 21/02; G01R 21/133; G05B 15/02

(52) U.S. Cl. CPC G05D 23/1917; G05B 15/02; G01R 21/02; G01R 21/133

(57) ABSTRACT

A system includes a detection interface that detects signals from which house data and environmental data for at least one house can be collected. The house data includes at least power usage of the heating ventilation and air conditioning (HVAC) system of the house as a function of time. An analyzer calculates values of thermal loads of the house based on the house data and the environmental data by solving a stochastic thermal energy balance equation for the house using thermal load estimates. An output interface outputs information about the thermal loads of the house based on the calculated thermal load values.

### TECHNICAL FIELD This disclosure generally involves computer implemented methods and systems for determining the drivers of heating, ventilation, and air conditioning (HVAC) systems of buildings.

### BACKGROUND

Climate control systems of buildings are subject to various internal and external loads. Steps to improve the energy efficiency of a building are more effective when the relative impact of the various loads on the climate control system are known so that targeted action toward particular loads is possible. Improving the energy efficiency of buildings is desirable to reduce the cost to operate the climate control system and to reduce harmful environmental emissions.

### SUMMARY

Some embodiments involve a system configured to provide information about thermal loads of one or more houses. The system includes a detection interface configured to detect signal from which house data can be collected for at least one house. The house data includes at least power usage of the heating ventilation and air conditioning (HVAC) system of the house as a function of time. The detection interface also collects environmental data associated the house. An analyzer computes values of thermal loads of the house based on the house data and the environmental data by solving a stochastic thermal energy balance equation for the house using thermal load estimates. For example, the thermal load estimates may be provided by maximum a posteriori probability estimation deduced by an expectation-maximization algorithm (EMMAP). An output interface outputs an electrical signal that includes information about the thermal loads based on the computed thermal load values.

Some embodiments are directed to a computer implemented method. House data and environmental data for at least one house are collected and are provided as inputs to a physics model that is a stochastic thermal energy balance equation for the house. The house data is collected from a signal from the house that includes information about at least power usage of the heating ventilation and air conditioning (HVAC) system of the house as a function of time. The stochastic thermal energy balance equation is solved to obtain values for thermal loads of the house using thermal load estimates provided by maximum a posteriori probability estimation deduced by an expectation-maximization algorithm (EMMAP). An electrical signal output includes information about the thermal loads based on the calculated values of the thermal loads.

Some embodiments involve a system for providing control signals for altering one or more aspects of the house that changes absolute or relative values of one or more of the thermal loads. The system includes a detection interface configured to detect a signal from which house data for at least one house can be collected. The house data includes at least power usage of the heating ventilation and air conditioning (HVAC) system of the house as a function of time. The detection interface also detects at least one signal from which environmental data associated with a house can be collected. An analyzer calculates values of thermal loads for the house based on the house data and the environmental data by solving a stochastic thermal energy balance equation for the house using thermal load estimates provided by maximum a posteriori probability estimation deduced by an expectation-maximization algorithm (EMMAP). According to some aspects, an output interface outputs an signal that includes information that is based on the calculated thermal load values. According to some aspects, the output interface outputs an control signal that alters one or more aspects of the house that changes absolute or relative values of one or more of the thermal loads.

### BRIEF DESCRIPTION OF THE DRAWINGS

FIG. 1 is a block diagram of a system configured to identify the relative importance of HVAC system thermal loads in accordance with some embodiments;

FIG. 2 illustrates a physics model of a house that may be used in the statistical analysis, of the thermal loads in some embodiments;

FIG. 3 provides the output from the analyzer showing how each of the fractional thermal load values compares to the overall power demand of a system in air conditioning mode in accordance with some embodiments;

FIG. 4 shows the highest value thermal load that is a heat source for each of the first 20 houses of FIG. 3;

FIG. 5 is a block diagram that illustrates a system configured to obtain the thermal load values of each house across a population of houses in accordance with some embodiments;

FIG. 6 illustrates an approach for using the model output to understand consumption within each house compared to other houses in a population of houses in accordance with some embodiments;

FIG. 7 illustrates another method of comparing houses in a population showing the three lowest and three highest energy users in accordance with some embodiments; and

FIG. 8 is a plot that shows an output from the model, an effective setpoint, compared to an actual characteristic setpoint for a house in accordance with some embodiments.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

Systems and methods disclosed herein relate to making inferences about the structural and behavioral drivers of heating, ventilation, and air conditioning (HVAC) system loads in buildings. The disclosed approach can facilitate recommendations to energy consumers based on the drivers of the HVAC loads. These recommendations, if acted upon, can enhance comfort of building residents while reducing energy usage. In some embodiments, the inferences about system loads can be used to compare the relative importance of different loads of one building. For example, information about the relative importance of different loads may be provided to the building owner so that targeted action to reduce the impact of the identified loads can be taken. In some embodiments, one or more aspects of the building, e.g., automatic blinds, fans, or the operating parameters of the HVAC system itself, can be controlled based on information about the loads on the HVAC system.

Some embodiments consider inferences that can be drawn across a population of buildings. Inferences about the impact of different loads across the population of buildings can be used to understand the likely reasons why one building's HVAC system energy usage is extraordinary in the context of the population of buildings. Comparison of the energy usage of the buildings in the population and their HVAC loads can be used by an electric utility, for example, to target its outreach and communication efforts based on an understanding of the most likely drivers of HVAC demand. Currently, utility incentive programs are often offered on a first-come, first-served basis to a subset of the population, or based on social targeted marketing without advance knowledge of each customer's technical opportunity for reducing energy consumption. One example case for the approaches disclosed herein is for utilities to target their residential energy efficiency (EE) incentive programs based on the comparison of different HVAC system loads across a set of homes. The approaches described herein are particularly useful for situations where it is not practical or cost effective to perform an extensive on-site assessment of the house, nor to populate the house with sensors and communication that could directly measure all important modes of heat transport and energy usage. According to some approaches described herein, recommendations for improving energy efficiency may be made using monitored data of heating and/or cooling power usage for a house that is readily available, e.g., by the power company.

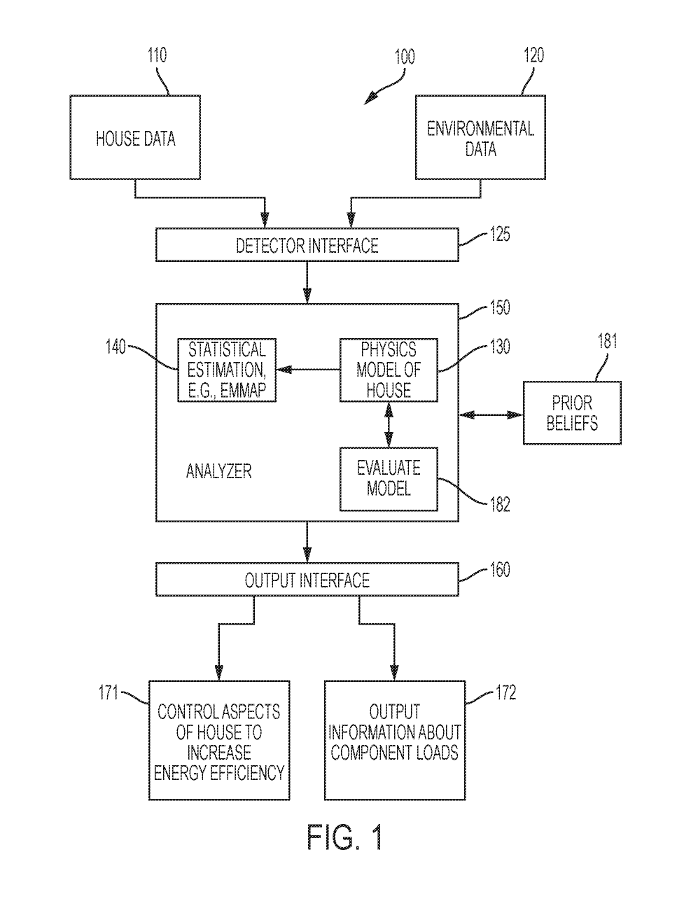

FIG. 1 is a block diagram that illustrates a system 100 in accordance with some embodiments. In some implementations, the system 100 is configured to identify the relative importance of HVAC system thermal loads in a single building. In some implementations, system 100 may be configured to make comparisons across a population of buildings. Note that the terms “home,” “house,” and “building” are used interchangeably herein.

As shown in FIG. 1, a detection interface 125 detects at least one signal from which house data 110 for at least one house can be collected. The house data 110 includes at least power usage of the HVAC system of the house as a function of time, e.g., a time series of the power usage, but may also include power usage of other appliances (non-HVAC appliances) of the house. Power usage data for the house may be or comprise a series of times that the HVAC system turns on and off, for example. The house data is extracted from the signal and is collected by the detection interface 125.

In some embodiments, the detection interface 125 may be coupled to monitor the main power circuit of the house and/or one or more sub-circuits of the house and to obtain the power usage of the HVAC system and/or other house data from an electrical signal produced by monitoring one or both of these circuits. For example, in embodiments in which the detector interface 125 is coupled to the HVAC system sub-circuit, the detector interface 125 may collect the house data by detecting times that the HVAC system turns on and turns off and/or by sensing current drawn by the HVAC system sub-circuit. In scenarios in which the HVAC system is fuel-based, the detector interface 125 may be configured to sense fuel drawn by the HVAC system. In situations where the detection interface 125 monitors the main power circuit of the house, the detection interface 125 may comprise circuitry, e.g., circuitry and/or a processor implementing software instructions, configured to disaggregate the HVAC system power usage from power usage of non-HVAC appliances.

Some houses may have monitoring devices installed within the house, e.g., smart thermostats and/or energy usage analyzers. In these embodiments, the detection interface 125 may include receiver or transceiver circuitry configured to receive signals from the installed monitoring device. The detection interface 125 may be configured detect signals that include the house data, or signals that include information from which the house data can be obtained. For example, the monitoring device may communicate the signals to the detection interface 125 via a wired or wireless network connection.

The detection interface 125 is configured to detect at least one signal from which environmental data 120 associated with the house can be collected. The environmental data 120 can include at least outside temperature in the vicinity of the house and other environmental data such as temperature of the earth beneath the house, humidity, radiation, cloud cover, wind speed and direction, rainfall, insolation, etc. In some embodiments, additional data, such as physical configuration of the house, e.g., square footage, number of stories, shading, the activity of people in the house, and/or other data may also be used as an input to the analyzer 150.

In some embodiments, the detection interface 125 itself may include sensors, e.g., thermometer, humidity, rainfall, wind sensors and/or other sensors, that are set up to sense at least some environmental conditions associated with the house. In other embodiments, the environmental data may be sensed and stored by an external system. In these embodiments, the environmental data may be obtained by the detection interface 125 from the external system. For example, weather information may be stored on a remote external weather data server and the detection interface obtains the weather information by communicating with the remote external server over a wireless network. In scenarios where a monitoring system that is capable of obtaining environmental information is installed in the house, the detection interface 125 may be configured to receive signals from the monitoring system and to collect the environmental data from the signals. In yet other embodiments, the detection interface 125 may obtain some environmental data from signals obtained from its own sensors and to acquire other environmental data from signals received from a remote external system.

The analyzer 150 includes a physics model 130 of the house comprising a stochastic thermal energy balance equation that is integrated over cycles of the HVAC system. The thermal energy balance equation is used to provide a statistical estimation 140 of the value of thermal loads. The thermal load values depend on various physical parameters of the house and/or environmental parameters that affect the house. For example, in some implementations, the statistical estimation calculation may iteratively attempt different combinations of the thermal load values until the estimator reaches convergence. In some embodiments, the estimates are calculated by maximum a posteriori probability estimation deduced by an expectation-maximization (EMMAP) algorithm. The analyzer solves for a probability estimation taking into account prior beliefs which are an understanding of the probability distributions of the thermal load values before the analysis step. The thermal load values obtained by the analysis are posterior beliefs which are the updated probability distributions of the prior belief thermal load values after the analysis.

The analyzer 150 takes in the house data 110, the environmental data 120, and/or other data and calculates the thermal loads may be mean and standard deviations of Gaussian distributions (or other distributions). In some embodiments, the analyzer 150 may determine the absolute and/or relative contribution of each thermal load to the HVAC power usage. Information about the thermal loads calculated by the analyzer is included in a signal that is an output of the output interface 160. For example, the information may include absolute values of the thermal loads and/or values of each of the thermal loads relative to the total thermal load of the house.

In some embodiments, the analyzer 150 generates a control signal 171 based on the information about the thermal loads. The control signal is output by the output interface 160 and is electrically coupled to alter some aspect of the house to enhance the energy efficiency of the house in response to the information about the thermal loads, e.g., the output signal alters one or more aspects of the house that changes the absolute or relative values of the thermal loads. For example, the control signal may control lowering or raising window coverings, increasing or decreasing ventilation, turning appliances on or off, altering the operation of the HVAC system, and/or initiating another action that changes the proportional contribution of the thermal loads.

In some embodiments, the analyzer 150 generates information about relative importance of different thermal loads which is provided via the output interface 160. The analyzer 150 may determine an effective setpoint for the thermostat of the house and the information output by the output interface 160 may include the setpoint information. If the effective setpoint determined by the model differs significantly from the set point registered in the thermostat, that could mean the thermostat is not in a location which is representative of the house as a whole, or it could mean the calibration of the thermostat is poor, as examples. When ranking homes by how low the air conditioning is set, looking at the effective setpoint returned by the model could be performed before recommending or acting on a recommendation based on the reported or thermostat recorded set point.

Information about the thermal loads, e.g., absolute or relative values of the thermal loads or other information determined by the analyzer 150, may be provided to an operator via electrical output signals from the output interface 160. In some embodiments, the information provided through the output interface 160 may be in the form of recommendations for reducing overall energy usage that have been developed by the analyzer 150. The recommendations can allow the homeowner to apply cost effective energy efficiency improvements that target the thermal loads associated with a higher proportional energy usage than other thermal loads.

In some implementations, the information provided by the analyzer 150 may be a comparison of the significance of different loads within a home and/or comparisons of different loads across a population of homes. These comparisons are valuable on a statistical basis to understand which homes are most likely to be typical or extraordinary compared to others or which drivers of energy demand are most likely to be significant for a given home.

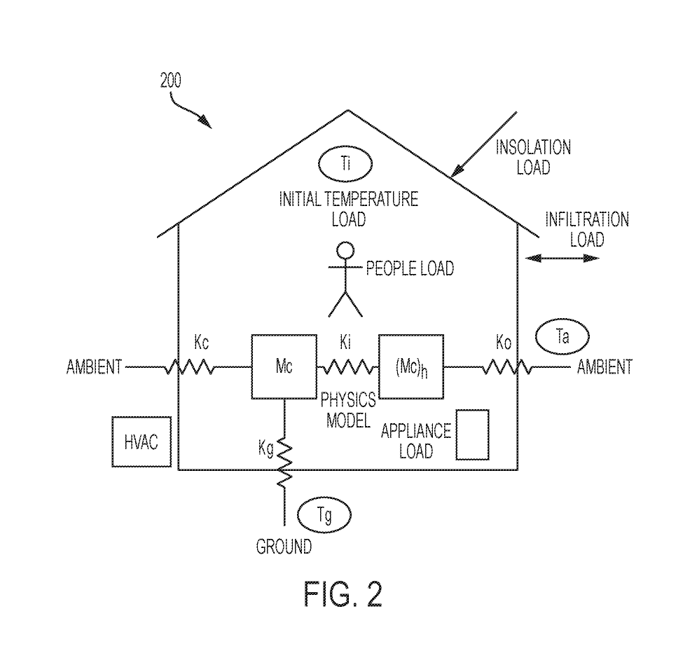

FIG. 2 illustrates a physics model of a house 200 that may be used in the statistical analysis, e.g., EMMAP analysis, of the thermal loads in some embodiments. The physics model in this example includes a two thermal mass model comprising the thermal mass of the circulating air, Mc, in the house and the thermal mass of the structure (walls, ceiling, floor, roof, etc.) and contents (furniture, draperies, rugs, etc.) of the house, (Mc)ₕ. According to this model the thermal mass of the circulating air is the mass of the circulating air multiplied by the specific heat of the air and the thermal mass of the structure and contents of the house is the mass of the structure and contents multiplied by the specific heat of the structure and contents. In some implementations, the contents of the house may also include non-circulating air, e.g., air in the basement or attic. Note that in some embodiments, a single mass model or a model that includes more than two thermal masses could be used. Ambient and Ground may be assumed to be infinite thermal masses and their temperatures are inputs to the physics model. The ground temperature may be assumed to be fixed or slowly varying over a season, and the varying ambient air temperature can be drawn from environmental data in some implementations. The inside circulating air, Mc, and the house structure and contents, (Mc)ₕ, may be assumed to have finite thermal masses and time-varying temperatures.

The physics model may consider the thermal energy balance of the house during blocks of time when the HVAC system is actively cycling. The term “active cycling” is meant to describe the situation where the indoor temperature is being controlled within the dead-band of the thermostat, as opposed to the situation where the HVAC system is turned on to do an initial cooling down or heating up of the house from some uncontrolled temperature. In some embodiments, it is assumed that active cycling is occurring when the HVAC system is running with a duty cycle that is larger than a lower bound (such as 0.1) and smaller than an upper bound (such as 0.9). A set of n consecutive active cycles comprises a block, where n is greater than 5, for example.

The inside air temperature may be assumed to cycle around the setpoint for the HVAC (which is an output of the model) and the temperature of the house structure/contents can be solved iteratively based on an initial temperature at the beginning of each block. This initial temperature is also an output of the model.

As shown in FIG. 2, the thermal mass of the house structure/contents (Mc)ₕ and the inside air Mc each have a thermal conductance to ambient, Ko and Kc, respectively. Additionally, there is a thermal conductance (Ki) between (Mc)ₕ and Mc. The thermal mass of the circulating air has a thermal conductance to the ground, Kg. Differences between temperatures at each of the thermal masses create conduction loads. Other loads, e.g., insolation load, infiltration load, non-HVAC appliance load, people load shown in FIG. 2 enter the model as heat sources to either the circulating air thermal mass Mc or the house structure/contents thermal mass (Mc)ₕ.

In general, the physics model is a thermal energy-balance equation that is given by:

$$M c \frac{dT}{dt} = {Q}_{all} + {Q}_{hvac} , \qquad ( Eq . 1 )$$

where t is time, T is the temperature of the circulating air of the house, Qₐₗₗ indicates a number of terms that specify various loads on the HVAC system and Q_{hvac} the amount of cooling or heating of the circulating air by the HVAC system. In Eq. 1, Mc is the thermal mass of the circulating air in the house, the temperature of which is measured by a thermostat that controls the cycling of the HVAC system in order to keep the temperature within a small range (deadband) around a setpoint.

Integrating over one cycle, assuming that the internal temperature is the same at the beginning and end of the cycle, yields 0 for the integral of the left hand side of the Eq. 1. The integral of the load on the right side of Eq. 1, Qₐₗₗ, therefore equal in magnitude to the integrated is HVAC cooling/heating, Q_{hvac}. An on-off cycle of the HVAC system is the period from the time that the HVAC turns on until the HVAC system turns on again. It may be assumed that over an on-off cycle of the HVAC system, the internal temperature swings above and below the setpoint Tsp (as determined by the deadband) and the average T over the cycle is Tsp. The average HVAC system cooling power is defined preliminarily as f Q_{hvac}⁰ where the amount of cooling or heating of the circulating air by the HVAC system, Q_{hvac}⁰, is considered to be constant when the system is on and f is the fraction of the cycle that the HVAC system is on.

The physics model provided by Eq. 1 above involves a single thermal mass. As illustrated in FIG. 2, in some implementations, the physics model includes two thermal masses, Mc and (Mc)ₕ, along with thermal conductances that connect these thermal masses with each other, with the ambient air, and with the ground. In the two thermal mass model, the mass of the circulating air, Mc, and the mass of the house structure/contents, (Mc)ₕ, are considered separately. The thermal equation for the circulating air, Mc, is given by Eq. 1 above. The thermal equation for the structure/contents of the house, (Mc)ₕ, at temperature Tₕ is given by:

$${( M c )}_{h} \frac{{dT}_{h}}{dt} = {K}_{i} ( T - {T}_{h} ) + {Q}_{h} \qquad ( Eq . 2 )$$

where Qₕ is the sum of load values that add or draw heat from the house structure/contents, T is the temperature of the circulating air, and Kᵢ is the conductance between the house structure/contents and the circulating air. Additional information regarding the solution of the two mass physics model is provided in more detail below.

As indicated in FIG. 1, the house data and environmental data are inputs to the analyzer which solves the thermal energy balance equations expressed by the physics model. The house data at least includes power usage of the heating ventilation and air conditioning (HVAC) system of the house as a function of time. In some embodiments, the house data also comprises one or more of the physical configuration of the house, the coefficient of performance (COP) of the HVAC system, the efficiency of the HVAC system, and the number of setpoints of the HVAC system.

The timing and total energy usage for each HVAC cycle of interest provides the HVAC power usage. In some scenarios, the detection interface (see 125, FIG. 1) is coupled to detect on and off transitions of the HVAC system. The HVAC power usage data used by the analyzer can be discerned from the on and off transitions of the HVAC system. Although it is preferable to have data that also includes the HVAC power consumption during each cycle of interest, explicit power consumption data is not required.

In some scenarios, the detection interface 125 is coupled to the main power circuit for the house and is configured to detect overall power consumption of the house with respect to time. The detection interface 125 and/or analyzer can employ software disaggregation to deduce HVAC versus non-HVAC power usage as time series data. The overall power consumption may be disaggregated at the level of distinct circuits to obtain household power usage at intervals, e.g., 1-minute intervals. In these embodiments, the power data is acquired at a frequency that is high enough to distinguish the electricity used by the HVAC system versus the electricity used elsewhere in the house, e.g., at a frequency higher than the typical frequency of HVAC cycles. Overall power consumption data for a house at a sufficiently high frequency can be combined with HVAC on-off time series data from a networked thermostat. The disaggregated data may be integrated over each on-off HVAC cycle before input to the statistical analyzer.

In some embodiments, data for the non-HVAC power consumption in the house during each HVAC cycle of interest is also available via the detection interface 125. All electrical power draws of the house that are not HVAC may be lumped into one appliance load. The appliance load includes loads from items such as lights and computers that draw electricity and create a heat load in the house. The appliance load may be a lumped term determined by the electrical power draws of the non-HVAC appliances over the HVAC cycle of interest.

In some configurations, HVAC power usage data may come from sub-circuit monitoring. For example, the detection interface 125 may include a current transformer coupled to a circuit that supplies energy primarily to a heater or air conditioner. As another example configuration, the detection interface may be coupled to a networked thermostat that reports cycling times. The HVAC power usage data may be obtained based on the cycling times, possibly with an assumption about the typical power draw of the air conditioner or heater.

In the case of a forced-air gas-fired furnace, electricity usage data may give an indication of the cycling of the furnace even if the gas itself is the primary fuel that is used to provide the heat. With current monitoring infrastructure, data of HVAC power usage are most likely to be in the form of electricity usage. However, monitoring of gas usage for heating or air conditioning could serve the same purpose. The detection interface 125 may include a flow meter or pressure meter configured to detect gas usage of the HVAC system.

In the absence of power usage vs. time at a sufficiently high frequency for collecting the non-HVAC power consumption in a house, the heat from non-HVAC appliance loads can be treated as a “hidden” variable in the EMMAP analysis. The hidden variable is solved for, rather than being data input into the model, resulting in less data and another variable to fit. The accuracy of the inferences will be affected, but in some cases the accuracy will still be good enough to make valuable recommendations.

Although not required, data from a networked thermostat or thermometer could be used to indicate the thermostat setpoint. Examples of when such data could be helpful include when the set point varies and when there is not a lot of active cycling of the HVAC system. In this scenario, instead of solving for the setpoint, if it is measured accurately, then the setpoint switches from being something determined to data input into the model.

Some implementations involve an HVAC system controlled by a bang-bang thermostat with a small hysteresis or dead-band. (such as 1 degree Celsius). Though this model is a highly-simplified description of a real house, it is useful because in some circumstances there may not be enough information in the usage data alone to construct a highly detailed model. A simple implementation is intended to include enough terms to describe the basic modes of heat generation and transport for a typical house, without assuming that there is detailed knowledge of the house's physical properties or extensive sensing of variables throughout the house. Thus, some embodiments may be directed to the development of a “minimal viable model” that will elucidate the factors of interest so as to determine from the available data the values of some thermal loads that are physically meaningful with a statistical accuracy that is high enough to be of value.

The coefficient of performance (COP) or HVAC system efficiency may be the appropriate measures of the amount of heating or cooling power for a given amount of external energy draw. Either the COP or HVAC system efficiency can be used as an overall scaling factor in the model. If only cycling data (such as from a thermostat) are available, then the typical power draw of the non-HVAC appliances can similarly be an overall scaling factor.

If thermostat time series data are not available, it can be assumed that there exists a thermostat setpoint when the HVAC system is cycling on and off with some regularity. Parameterizing the setpoint, the model may integrate over an HVAC cycle which is the atomic data point and the model assumes that there is an energy balance (e.g., between the left and right sides of Eq. 1 and Eq. 2) over this time scale. In some implementations, there is one thermostat set point that describes all active cycling of the HVAC system, e.g., all active cooling during the summer. In some implementations, there may be multiple thermostat setpoints that change regularly with the time of day, or for each block, or in some other fashion.

Houses may have a distribution of heat capacities due to the associated solid matter in the house. The solid matter in the house is accounted for in the house structure/contents thermal mass. There are thermal time constants associated with the house structure/contents that differ significantly from the thermal time constant for the response of circulating air inside the house to heat loads. Typical data on power usage is generally insufficient for de-convolving the population of time constants for solid matter, so it is possible to lump the heat loads into the two thermal masses representing the circulating air and the other house elements. Note that three or more thermal masses with three or more time constants could also be used in the physics model.

In addition to house data, environmental data for outside the house is also used as an input to the statistical analyzer. These data may be at a time resolution, such as hourly, that is different from the HVAC power usage data, e.g., 1 minute intervals. The environmental data includes at least temperature of the air outside the house and may also include one or more of ground temperature beneath the house, humidity, wind speed, wind direction, indication of cloud cover and insolation. In scenarios where the insolation is not directly available, models, experiments, and/or the location of the house may be used to infer insolation from information about cloud cover, visibility, temperature, humidity, time of day, and/or other information. Environmental data ideally are from measurements as close to a house as possible. They may be data from an environmental station, or an inference of local data based on data from one or multiple environmental stations that are more distant. Other sources of data might include insolation data from a local photovoltaic installation, outdoor temperatures measured by homeowner-installed thermometers or even by outdoor temperature sensors on cars.

The house data and the environmental data are inputs to a physics model of the analyzer. As previously discussed, the physics model is a thermal-energy balance equation that may be integrated over each cycle of the HVAC system. The analyzer inputs house data, environmental data and optionally other types of data and outputs estimates for multiple loads (the thermal loads of Qₐₗₗ,) on the HVAC system. In some implementations, a Gaussian random variable is included in the model as an additive noise term to take into account random errors in the house and/or environmental data.

The thermal loads may comprise one or more of initial temperature load, insolation load, non-HVAC appliance load, conduction to ground load, conduction to ambient load, infiltration load, and people load, for example. The division of loads into those which heat the thermal mass of the circulating air and those which heat the thermal mass of the house structure/contents in the physics model is a configurable division. In some embodiments, the thermal energy balance equation for the circulating air may include non-HVAC appliance loads, people loads, infiltration load, a conductive load to the ground, a conductive load to the house structure/contents, and a conductive load to the outside air. The thermal energy balance equation for the thermal mass of the house structure/contents may include a load from conduction with the air, a load from insolation, and a load from conduction with the outside air.

For example, in some implementations, the entire insolation heat load may be assigned to the house structure/contents thermal mass. This assignment may be useful, for example, because the insolation in a typical, newer suburban house hits the roof and walls and heats the attic space and the externally facing walls. The circulating air does not absorb any significant number of photons. Of the photons that go through windows, which should be a minority of the photon flux, these photons will be absorbed by some matter, and that matter is going to have a thermal time constant longer than the circulating air. So even for photons that go through windows and heat some mass inside the house, including that insolation heating in the second thermal mass may be appropriate. Assigning the total insolation load to the house structure/contents thermal mass is one implementation and other inferences could be made about whether the physics model indicates that this load heats only the second thermal mass (house structure/contents), only the first thermal mass (circulating air), or a combination of the two.

Note that the overall sign of the conduction loads depends on the relative difference in temperatures and could be negative or positive. Although in some embodiments, each heat load is pre-assigned to a particular thermal mass, (e.g., the circulating air thermal mass or the house structure/content thermal mass) of the model, in other embodiments the assignment of loads to the circulating air or house structure contents may be performed by the model. In some scenarios, part of the analysis is to choose between a pre-assignment of the heat loads or an assignment of heat loads by the model based on which gives a posteriori higher likelihood for the data.

As previously discussed, in some cases the term for heat generated by non-HVAC appliance loads is simplified and may be a lumped load. The amount of heat that goes into the house from different appliances varies and the time scales of that heat transfer are not the same for all appliances. The model may assume that the time constants for the non-HVAC appliance loads are faster than the relevant times for the HVAC cycles. As described herein, the appliance load may be determined based on the non-HVAC portion of the total power usage of the house.

In the two thermal mass model, the temperature of the house structure/contents can be an initial negative or positive load on the circulating air. It is the circulating air temperature that is controlled by the air conditioner. The initial load involves a thermal inertia or thermal storage associated with the structure and/or contents of the house, which may act as a heat sink or a heat source when the HVAC system turns on. At the beginning of each active cycle, the thermal mass of the house structure/contents (which may be modeled as being at one uniform temperature) has some temperature offset ε with respect to the circulation air. The model may estimate this temperature offset for each block of HVAC system active cycling. The load created by this temperature offset and the finite thermal conductance between the thermal mass of the house structure/contents and the thermal mass of the circulating air is the initial load.

In scenarios where there is an absence of time series data from a thermostat, the physics model may not try to fit data outside of time periods with active HVAC cycling. That means the initial temperature of the house at the beginning of each period of active cycling (each block) is another variable to be estimated. The model may estimate a distinct initial temperature load value for each block, such that there are many initial temperature loads deduced for the house when the data are considered over a long term, e.g., an entire cooling season. Because there is one value for each block, this can add a substantial number of fitting parameters comprising the initial temperature loads to the model.

In the some embodiments, at each block, the initial temperature load is drawn from a log normal distribution. The initial temperature load could also be included as a hidden variable in the EMMAP solution or drawn from another distribution (such as one of two variables or a mixture of Gaussians).

A model for the initial temperature state of each block of HVAC cycling may be developed thereby reducing the dimensionality of this vector of unknowns. In some implementations the initial temperature states are assumed to follow a random distribution without additional information. In other implementations meta information (e.g. time of day when HVAC cycling begins) or data outside of the time period of HVAC cycling are used to fit a model to the initial temperature.

Both a thermal conduction between the internal circulating air and the above ground environment and a thermal conduction between the internal circulating air and ground may be considered, with different conductance values for each. The use of these loads takes into account the scenario wherein crawl spaces and basements may be significantly cooler than the rest of a house in the summer, for example. In addition, the ground temperature generally changes much more slowly than the outside air temperature. In some embodiments, the ground temperature is assumed to be a constant value corresponding to the average air temperature over a long term, e.g., a number of months.

The physics model may take into consideration how insolation varies with time at a house. For example, in some implementations a simple insolation model can be based on total cloud cover. Precipitation can also affect solar radiance, however, in many implementations the precipitation can be ignored. If precipitation data is available, the precipitation data can be considered yielding an overall reduction in the insolation that scales as a negative exponential of the rainfall rate.

For example, clear sky solar radiance, I_{G}, without clouds may be expressed as:

I_{G}=1.1 I_{Direct};

I_{Direct}=1.353 kW/m² [(1−0.14 h)0.7^{(AM}^{^{0.678}}⁾+0.14 H], where h 32 altitude≦3 km; AM =air mass;

$$δ = {sin}^{- 1} \{ sin ( 23.45 ° ) sin [ \frac{360}{365} ( d - 81 ) ] \} ,$$

where d=day of the year and January 1 is day 1;

αₘₐₓ=maximum elevation angle=90°−φ+δ, where φ=latitude (greater than 0 in the northern hemisphere); and

θₘₐₓ=90°−αₘₐₓ=φ−δ, where θ=zenith=90°−α.

Incorporating clouds and precipitation into the above model yields:

f_{prcp}=e_^{rain}^{_{/0.1 inches per hour}} and R=R₀(1−0.75e^{3.4})f_{prcp}.

Insolation per unit area can be assessed for an east-facing surface, a west-facing surface, and a horizontal surface yielding three separate insolation loads and three separate effective areas, AinsolE, AinsolW, and AinsolH, that respectively represent the effective areas for a house that are exposed to insolation in these three directions.

The insolation per unit infiltration area for a home may be calculated using environmental data, with a model parameter of Tset, also referred to as Tsp, which is the thermostat setpoint that represents the typical temperature of the air inside the home.

Infiltration of outside air to a home, through leaky construction, through open doors and windows, and through intentional ventilation systems, can create a load on the HVAC system. The infiltration load is related to the infiltration rate of air, the enthalpy difference between outside and air and inside air that must be removed by the HVAC system. In the case of an air conditioning system, the enthalpy difference between outside and air and inside air that must be removed by the HVAC system includes sensible and latent components as determined by temperature and humidity. In some implementations of the model, the humidity of the indoor air can be fixed, or the humidity of the indoor air can be an input if there is some measurement of the value, or the humidity of the indoor air could additionally be an estimated fit parameter in the model. In some embodiments, a fixed value of the specific humidity can be chosen, e.g., 8 g water/kg air, for determining infiltration.

In the case of a heater, the enthalpy difference between outside air and inside air that must be removed by the HVAC system is most likely only sensible heat. The enthalpy difference between outside air and inside air can be calculated using the equation:

Q=A_{L}\sqrt{Cₛ}|ΔT|+C_{w}U²

where Q is the airflow rate (in units of cfm), A_{L} is the effective air leakage area (in units of in²), Cₛ is the stack coefficient (in units of cfm²/in⁴·°F.), ΔTis the average indoor-outdoor temperature difference for time interval of calculation (in units of °F.), C_{w} is the wind coefficient (in units of cfm²/in⁴·mph²), and U is the local average wind speed at the time interval of the calculation (in units of mph). This calculation includes a stack coefficient and a wind coefficient, related to how tall a building is and how sheltered. These can be assumed or input from further information about construction and local environment of a house.

In addition to actions by occupants that alter infiltration, insolation, and appliance load heats, people generate a people heat load in varying amounts through activities in daily living and from body heat. For people behaviors, in some embodiments a relatively simple stochastic term is added to model the resulting heat source due to people, using a framework that could include more sophisticated people behaviors as desired and indicated. The baseline model can be a one-sided random variable to describe people behavior. In general, people do things that generate heat, but rarely do anything that would amount to a net cooling of a house when the HVAC is on. (Exceptions to this assumption include people who both run the HVAC and open windows and doors to let cool air in, as an example.)

In some implementations, a stochastic model for heat generated by people may include correlated behavior over time and possibly with other variables. For example, if people are generating a lot of heat in one HVAC cycle, there is a higher likelihood that they will continue to do so in the next cycle. Thus, in some embodiments, the physics model uses statistical models for the heat generated from people behaviors, such as models with temporally correlated amplitude. In simpler models, any such correlations may be ignored and the people load may be assumed to be a random variable selected from a log normal probability distribution.

For solving the coupled differential equations 1 and 2 set forth above, firstly the equation for Tₕ may be solved:

Tₕ−Tₛₚ=δₕe^{-α}^{₁}^{t}+∫₀^{t}e^{-α}^{₁}^{(t-τ)}qₕ(τ)dτ (Eq. 3)

where qₕ=Qₕ/(Mc)ₕ+αᵢ(T−Tₛₚ), (Eq. 4)

where T is the temperature of the circulating air; Tₕ=temperature of the structure/contents, Tₛₚ=set point temp; (Mc)ₕ is the thermal mass of the structure/contents of the house; δₕ is the initial temperature difference between Tₕ and Tₛₚ; 1/αᵢ is the thermal time constant defined by the thermal mass of the house structure/contents and the conduction from thermal mass of the house structure/contents to air, which mathematically is Kᵢ/(Mc)ₕ.

The mean of this equation over a cycle is calculated under the approximation that 1/αᵢ is much greater than the cycle time of the HVAC system. The load Qₕ is assumed to not vary significantly over one cycle. If environmental loads are to be more precisely integrated over cycles, this would have to be taken into account in the calculation. With further simplifications, breaking the double integral into a sum of integrals over cycles, the mean temperature difference is defined for the j-th cycle:

$${〈 {T}_{h} 〉}^{( j )} - {T}_{sp} \sim δ {e}^{- α {t}_{j}} + \frac{1}{{( M c )}_{h}} \{ ( \frac{1}{2} ) {〈 {Q}_{h} 〉}^{( j )} Δ {t}_{j} + {\sum }_{k = 1}^{j - 1} {〈 {Q}_{h} 〉}^{( k )} {e}^{- {α}_{i} ( {t}_{i} - {t}_{k} )} Δ {t}_{k} \} \qquad ( Eq . 5 )$$

where in this equation Δt is the elapsed time of a cycle and δₕ is Tₕ−Tₛₚ at the starting time. The sum in Eq. 5 is the sum over all cycles in the same block preceding cycle j.

This mean value of the temperature of the house structure/contents can be inserted into the thermal energy balance equation for the circulating air (such as where the conduction load between air and house structure/contents is defined) and it is the thermal energy balance Eq. 1 that becomes the main part of the EMMAP algorithm. The thermal masses and conductances in this thermal model are diagrammed schematically in FIG. 2.

Some embodiments are directed to using the thermal energy balance equation of the physics model in a statistical learning algorithm to estimate physical parameters characterizing thermal loads that characterize the thermal behavior of the house. In the illustrated example, the physics model is a simple two-mass thermal model. In order to encompass in this model solution knowledge about expected values for each of the parameters in the model, a Bayesian solution, which incorporates prior beliefs (see element 181 of FIG. 1) about each of the parameters, can be input to the EMMAP analyzer. The parameters that are being determined in this particular example and the prior belief distributions being used in the example are listed below. Different parameters solved and/or other selections regarding the shape of the distributions from which they are drawn and the mean and variance of each distribution could be made. These prior beliefs could be adjusted with additional information about the homes, such as the age and building code or construction standards at the time, building materials or construction methods, orientation of home, geometry of home and windows, construction of attic, construction of basement or foundation, etc. Some of these prior beliefs are based on a house that is 2000 sq ft in size and further adjusted based on the overall area (Ah, in sq ft) and number of stories Ns of the house; these additional parameters are input and they may be assumed or known from data sources.

Three scaling factors, Sf₁, Sf₂, Sf₃, are defined to include expected physical dependencies on footprint, volume, overall floor area, and outside wall area of a house, respectively.

Sf₁=\sqrt{Aₕ/2000} (Eq. 6)

Sf₂=((Aₕ/Nₛ)+32 \sqrt{AₕNₛ})/(2000+32 \sqrt{2000}) (Eq. 7)

Sf₃=Sf₁²/Nₛ (Eq. 8)

There is an overall scaling factor in this model that may not be learned from the data. This is a measure of how much of the energy draw goes into actual cooling or heating; for the HVAC system, this is the nominal COP and for a heater, this could be efficiency. As disclosed herein, the inverse of that scaling factor is termed Rc.

Consider the case where there is no use of electricity in the house except for AC use. In this case, the thermal energy balance provides that the cooling performed by the air conditioning (AC) equals the sum of the heat coming into the circulating air from the various loads. In this case, the model can always balance the thermal energy perfectly by assuming the AC efficiency is zero (such that the AC is using electricity but not cooling anything) and at the same time finding values of all the loads are equal to zero. However, the appliance load heating drives the model away from concluding that the house is perfectly insulated and the AC is not cooling.

In many cases, the plug load is not a dominant contributor to the total thermal load and thus should not be relied on to dominate the learning of the AC coefficient of performance (COP). Instead, a COP is assumed and the data is scaled by the assumed COP, except for the plug load. The scaling of the plug load may be determined by the statistical loading. The scaling of the plug load can be considered to be 1/COP but in some scenarios it may not be reasonable to interpret the scaling of the plug load to be 1/COP and/or the resulting learned uncertainty of the value is so large as to make the result of little use. Thus, in some embodiments, the statistical learning may be more effectively accomplished using the thermal energy balance divided by COP.

In some embodiments, the COP of the HVAC system can be assumed to be equal to COP0f(T), where f(T) is some function of outdoor temperature. In some embodiments, the f(T) could also include indoor temperature.

Each of the thermal loads below is an output of the model, where the prior beliefs are inputs. Note that although lognormal or other specific distributions may be mentioned herein as prior belief distributions, these distributions are merely examples and in general any distribution could be used.

Tₛₚ: Thermostat setpoint in the model. There may be one setpoint that defines a house. Other choices could be made, for example, there could be a different setpoint chosen for different times of day, or for each block of active cycles. There may be different setpoints for workdays and weeknights. Prior belief for Tₛₚ is a normal distribution, e.g. with mean 25.5 and standard deviation 5. Units are degrees Celsius. Note that these values are examples of typical prior beliefs, and other values could alternatively be used.

AinsolE: Normalized by R_{c}, e.g., by dividing the thermal energy balance by COP, AinsolE is the effective east-facing area exposed to insolation. Prior belief for this output parameter is a lognormal distribution, for example with mean 0.5R_{c}(Sf₁) and standard deviation 2R_{c}(Sf ₁). The units of AinsolE are square meters. This prior belief could be adjusted with knowledge of the geometry and/or orientation of the home. Note that this area is an “effective” area, meaning the equivalent area if 100% of the insolation heated the thermal mass in the thermal energy balance.

AinsolW: Normalized by R_{c}, AinsolW is the effective west-facing area exposed to insolation. Prior belief is the same as for AinsolE. The units of AinsolW are square meters. This prior belief could be adjusted with knowledge of the geometry and/or orientation of the home.

AinsolH: Normalized by R_{c}, AinsolH is the effective horizontal surface area exposed to insolation. Prior belief is a lognormal distribution, assuring only positive values permitted. The mean of a default prior belief could be 5R_{c}(Sf₃) and standard deviation is 5R_{c}(Sf₃). The units of AinsolH are square meters.

Ainfil: Normalized by R_{c}, this is the effective infiltration area. Prior belief is a lognormal Distribution, assuring only positive values permitted. As examples, the mean of the prior is 0.05R_{c}(Sf₁²) and standard deviation is 0.15R_{c}(Sf₁²). The units for Ainfil are square meters.

1/COP0 or recCOP0: This is a scaling A/Rc on the appliance load where A is the fraction of the energy drawn by other appliances that becomes a heat load on the air. Prior can be chosen either as a log normal distribution or as a normal distribution centered at 0 and constrained to input only positive values. In the latter case, the mean is Rc and the standard deviation is 100Rc. This is dimensionless.

K_{c}: Normalized by R_{c}, K_{c} is the thermal conductance between the indoor air and ambient air. Prior belief is a lognormal distribution, assuring only positive values permitted, with mean 0.2R_{c}(Sf₂) and standard deviation R_{c}(Sf₂). The units of K_{c} are kW/K.

K_{g}: Normalized by R_{c}, K_{g} is the thermal conductance between indoor air and the ground. Prior belief is a lognormal distribution, assuring only positive values permitted, with mean 0.8R_{c}(Sf₂) and standard deviation 2R_{c}(Sf₂).

Kᵢ: Kᵢ is the thermal conductivity from the thermal mass of the house structure/contents to ambient. The units are kW/K. Prior belief is a lognormal distribution, for example with mean 0.8R_{c}(Sf₂) and standard deviation 5R_{c}(Sf₂). α: α is the inverse time constant of the thermal mass of the house structure/contents. Prior belief is a log-normal distribution, e.g. with mean and standard deviation equal to (Sf₂)/(Sf₁²). Units of α are in inverse days (1/day).

μ: μ is the mean of the associated normal distribution that characterizes the lognormal distribution of the latent people load. Prior belief is a normal distribution, for example with mean −1.8(Sf₁²) and standard deviation 3(Sf₁²). Units of μ are kW.

σ: σ is the standard deviation of the associated normal distribution that characterizes the lognormal distribution of the latent people load. Prior belief is a normal distribution, for example with mean 1(Sf₁²) and standard deviation 3(Sf₁²). Units are kW.

σ_{T}: σ_{T} is the standard deviation of the normal distribution (with mean 0) that characterizes the noise term. Prior is a normal distribution, for example with mean 0.5(Sf₂) and standard deviation 0.8(Sf₂). Units are kW.

δ: δ is the difference in temperature between the house structure/contents and the set point at the beginning of a block of active cycles. Prior belief is a normal distribution.

The thermal energy balance equation of the physics model may be solved by a maximum a posteriori (MAP) estimation using an EM algorithm (EMMAP). MAP refers to a maximum likelihood estimate of a parameter drawn from a posterior distribution, beginning with a prior distribution. The EM process is a way to estimate parameters in a model that includes missing or hidden variables (called latent variables). In the example physics model, the latent variable is the People load, which is characterized by a lognormal distribution. This is a model choice and other distributions could alternatively be chosen.

p(Θ|x) is an α posteriori probability function and, by Bayes Theorem, is proportional to p(x|Θ) p(Θ), where p(Θ), is the prior distribution for the parameters Θ. The EM algorithm is designed to converge to a local maximum of p(Θ|x) without directly calculating fp(x|Θ).

The model is described cycle by cycle as:

f⁽ⁱ⁾(x, Θ)−Qₚ⁽ⁱ⁾=∈⁽ⁱ⁾ . (Eq. 9)

The f ⁽ⁱ⁾(x, Θ) term in Eq. 9 encompasses all the terms in the thermal energy balance equation for the air (integrated over one cycle) aside from the “people” term Qₚ and the noise term ε. The observables, x, are the power draw of the ac (P_{ac}), the plug load Q_{plug}, environmental and time stamps. The size and number of stories of house (if available) are also inputs used to calculate scaling factors on the priors, as described previously. EMMAP outputs the characteristics ε of and Qₚ
(μ, τ, and σ_{T}) and the other parameters Θ as listed previously.

Following common notation for the EM algorithm, the latent variables Qₚ are denoted by z. The normal distribution of the noise term in Eq. 9 and the lognormal of Qₚ leads to Eq. 10:

$$p ( x , z \vert Θ ) = p ( x \vert z , Θ ) p ( z \vert Θ ) ∝ \frac{1}{z} exp ( \frac{- {( f - z )}^{2}}{2 {σ}_{T}^{2}} ) exp ( \frac{- {( ln z - μ )}^{2}}{2 {σ}^{2}} ) \qquad ( Eq . 10 )$$

where the subscripts that denote each cycle are dropped in Eq. 10. According to Eq. 10, the likelihood of a certain set of parameters, Θ, of which f is a function, given the observables x and hidden variable z is the product of the probability of the error term between f and the observation (assumed to be drawn from a normal distribution) and the probability of the latent variable (drawn from a distribution whose shape is defined and whose mean and standard deviation need to be estimated).

The E-step of the EM algorithm calculates the probability of a given latent variable z given the observables and the current estimate of Θ, \hat{Θ}. Equation 11 is the posterior distribution of z given x and the setting of Θ:

$$p ( z \vert x ; \hat{Θ} ) = \frac{p ( x , z \vert Θ = \hat{Θ} )}{\int p ( x , z \vert Θ = \hat{Θ} ) dz} \qquad ( Eq . 11 )$$

As an example, of a “soft” EM algorithm, in the E-step, there is an integration over all values of z. In the M-step (for iteration k), the estimate of Θ is updated to maximize the expectation value over z of:

A=log p(z, Θ|x) given x, \hat{Θ}. (Eq. 12)

The expectation value of A is E[A|x, \hat{Θ}]=∫p(z|x, \hat{Θ})Adz. (Eq. 13)

Equation 14 below is the model for f inserted into the stochastic equations above:

$$f = A C Power * ( \frac{COP}{{COP}_{0}} ) - ( {T}_{ambient} - {T}_{set point} ) * ( {A}_{infil} * {F}_{infil} * {c}_{air} + {K}_{c} ) - {K}_{i} ( δ {e}^{- α {t}_{j}} + \frac{1}{{( M c )}_{h}} \{ ( \frac{1}{2} ) {〈 {Q}_{h} 〉}^{( j )} Δ {t}_{j} + {\sum }_{k = 1}^{j - 1} {〈 {Q}_{h} 〉}^{( k )} {e}^{- {α}_{i} ( {t}_{j} - {t}_{k} )} Δ {t}_{k} \} ) - \frac{{Q}_{plug load}}{{COP}_{0}} + ( {T}_{set point } - {T}_{g} ) * {K}_{g} - {A}_{infil} * {F}_{infil} * ( A C condensation latent heat ) \qquad ( Eq . 14 )$$

As one embodiment, we assume Qh is equal to insolation and F_infil is the infiltration flow rate. The latent heat may be calculated from known engineering equations.

As previously discussed, the output of the EMMAP analysis includes parameters that can be used to compare the significance of different loads within a home and/or used to make comparisons across a population of homes. The model results for a given house may be evaluated further to estimate the statistical uncertainty on parameters that are output. This evaluation may be used to reject the validity of all model results for a home or to reject one component of the model results for a home. If, for example, the model outputs for a certain home an assessment of a thermostat setpoint of 25 C with a statistical error bar of 10 C, there is very little information about how this home's thermostat setpoint might compare to other homes' setpoints.

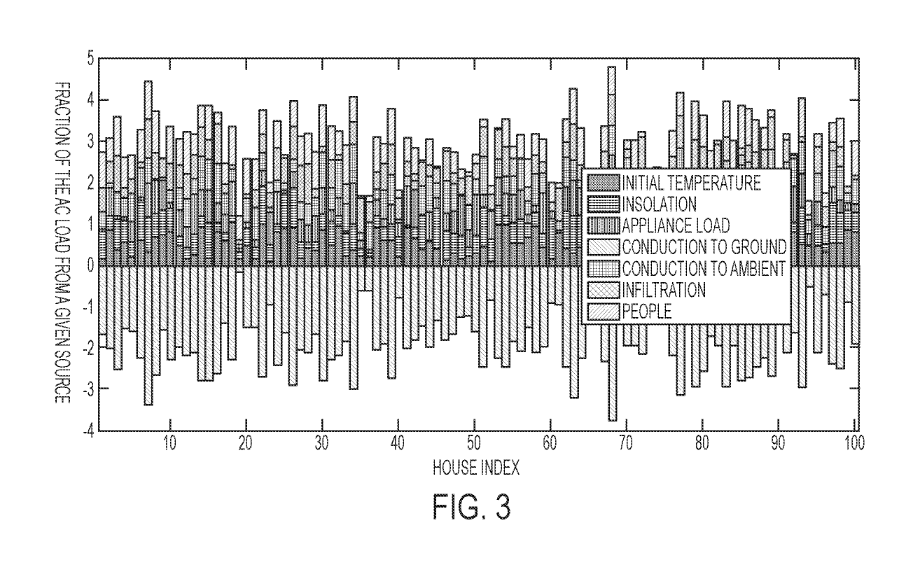

FIG. 3 provides the output from the EMMAP analyzer showing how each of the thermal loads compares to the overall HVAC power demand in air conditioning mode. The figure shows results for 100 houses, numbered from 1 to 100. FIG. 3 provides an output from a model showing how each of the thermal loads compares to the overall AC demand. The y-axis is a ratio of the a given load to the total AC load. Due to large conduction to ground in this set of simulated data, a given load can be larger than the total AC load (which is a sum of the negative and positive). For each house, the primary drivers of demand vary. The relative size of the bars for each house shows the relative importance of a given contribution for a house. This can be used to assess which measures might be most impactful for a given house. A house with a large insolation bar compared to the infiltration bar might benefit more from added shading, for example, than an upgrade to sealing around doors and windows. The y-axis is a ratio of the given load to the total HVAC load.

In FIG. 3, the loads can be either positive or negative, denoting whether they add to the heat that the AC must remove or reduce the heat that the AC must remove. The sum of the positive loads minus the sum of the absolute values of the negative loads equals one for each house. For the analyses summarized in this figure, the only negative loads are conduction from the house to the ground. In hot climates, often the ground and space under a house is cooler than the house itself.

For each house, the primary drivers of demand vary. The relative size of the bars for each house shows the relative importance of a given contribution for a house. This can be used to assess which measures might be most impactful for a given house; a house with a large insolation bar compared to the infiltration bar might benefit more from added shading, for example, than an upgrade to sealing around doors and windows.

For each house, the sum of each of the loads in the model can be compared to the overall usage from the HVAC system as shown in FIG. 3. Here, for each house, the fraction of the total HVAC power usage assigned to each individual load, as assessed by the model, is shown in a bar chart. The conduction to ground may be a heat sink rather than a heat source and a heat sink shows up as a negative load. The sum of the fractions (negative and positive) sum to 1.

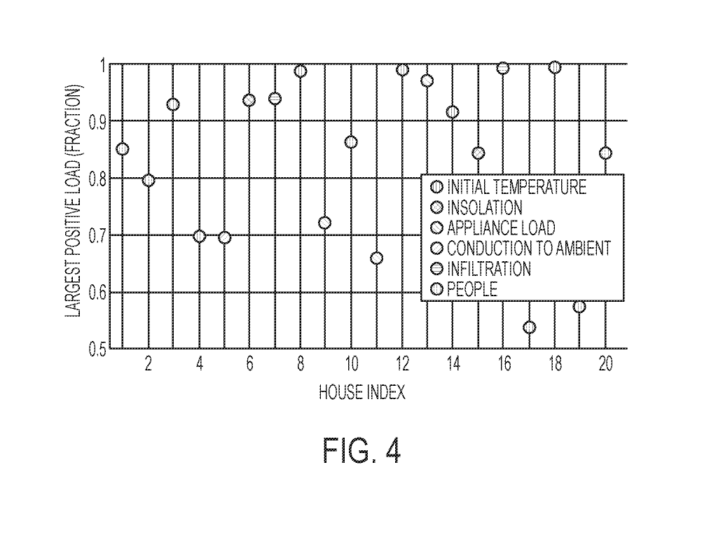

After the thermal loads are assessed as in FIG. 3, for a given house, the loads can be ranked for each house. For example, for Houses 1 and 19, the largest fractional load (as indicated by the size of the bar in the figure) is the People load; for Houses 2 and 18, it is the initial temperature load. FIG. 4 shows the largest load that is a heat source for each of the first 20 houses of FIG. 3 (this is the size of the largest bars for these houses in FIG. 3).

A utility can use the results of these rankings and comparisons within a home to choose, for a given home, what are the most appropriate incentives, messages, or offers to give to a particular household. If a utility, for example, is trying to encourage House 6 to reduce its energy usage, it might choose to focus on the model's inference that insolation is the dominant load on the house; the utility could offer rebates for window coverings, purchase of heat-reducing windows, for planting deciduous trees, or improving the thermal barrier between the attic and the rest of the home. With further inspection of the model results, the utility might also suggest taking advantage of the insolation by installing photovoltaic modules.

If the bill-payer from House 13 calls the utility call center to complain about its high utility bills during the summer, the customer service representative, understanding that appliance load is likely to be significant for this house, might start by asking questions to understand what heat generating appliances are in the house and suggesting that this be reduced.

In addition to making comparisons on a load-by-load basis, the output of the analyzer can be used to compare from house-to-house the parameters characterizing the thermal loads that are the output of the model. The unknown normalization of the COP of the HVAC system introduces an uncertainty in the comparison across homes. However, if the COP varies a small amount across homes, then the comparison of the effective insolation areas, for example, will be effective in showing which homes are most likely to have large areas of the house exposed to direct insolation (such as unshaded windows). Similar comparisons can be made about the thermostat setpoint, effective infiltration area, and the effective thermal conductances of each home.

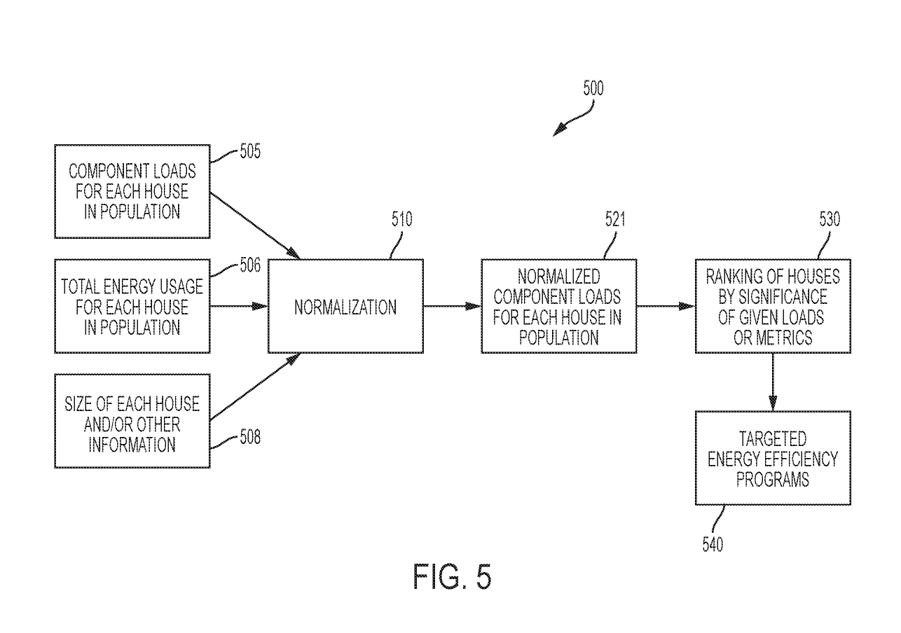

FIG. 5 is a block diagram that illustrates a system 500 configured to compare the thermal loads on each house across a population of houses. For comparison between houses, it is sometimes appropriate to first normalize 510 the thermal loads produced by the EMMAP analysis for multiple houses 505 e.g., by some measure of the size of the house 506 and/or the total energy usage 507 for each house. The thermostat setpoint physically is an intensive property, not related to the size of the home. Other thermal loads of the fit such as thermal conductances, infiltration, and/or insolation, are expected to be extensive properties, properties that are generally larger for larger homes. These properties also are subject to the unknown scaling factor (efficiency or COP or even that power of the AC or heater, depending on the data stream). In such cases, a comparison of the thermal loads among a population of houses may include normalization by the size (footprint or volume or overall square footage, for example) of the house, if such data are available. Further data about the HVAC appliance such as the rated power, efficiency, or COP, could be further used to improve the normalization.

The fractional loads for each house 521 may be determined. The houses may be ranked 530 by significance of the loads and/or metrics of potential/suggested changes. The ranking may be used in targeted energy efficiency communications 540 to energy consumers providing advice on the most cost effective steps to reduce energy consumption.

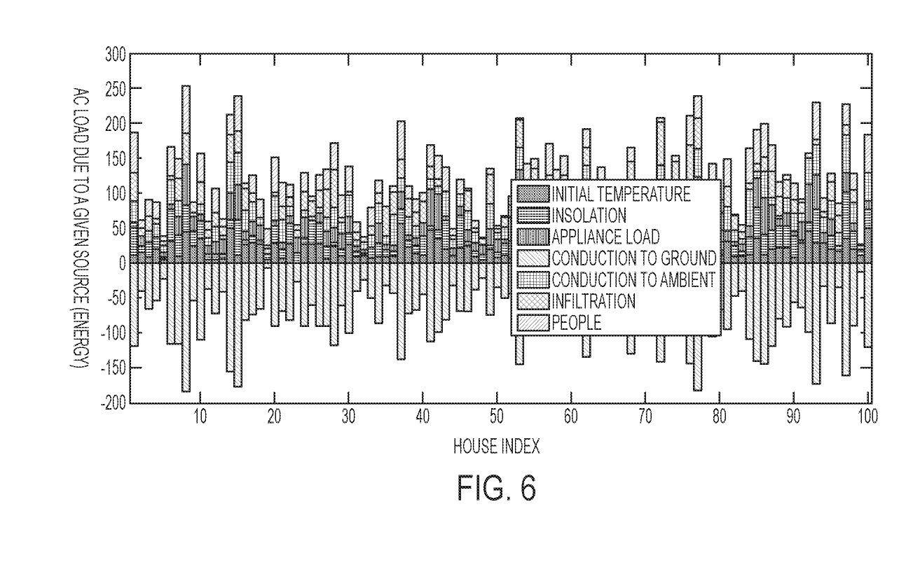

FIG. 6 shows an approach for using the system output to understand consumption within each house compared to other houses in a population. In FIG. 6, the load bar for each house is scaled by the overall energy draw of the AC so that the y-axis shows the amount of energy used (positive number) or energy use mitigated (negative number) by a given load, for each house. In addition to the evaluation of one house as shown in FIG. 3, this approach can be used to make house-to-house comparisons. In FIG. 6, the total energy consumption for AC is the sum of the bars for each house. The sub-bars show the total amount of energy consumption attributed to each load, with the negative number again indicating a heat sink. The overall cooling required from the HVAC system can be obtained by subtracting the magnitude of the negative values from the positive values.

Here, it is clear that the overall consumption of House 2 is small compared to the population and thus the total amount of energy savings potential for House 2, irrespective of the measure implemented, is small compared to other Houses. If a utility is selecting houses for the recipients of a weatherization program or simple messaging around closing doors and windows, the utility could first choose the houses which most likely have the largest total (rather than fractional) amount of energy loss through infiltration.

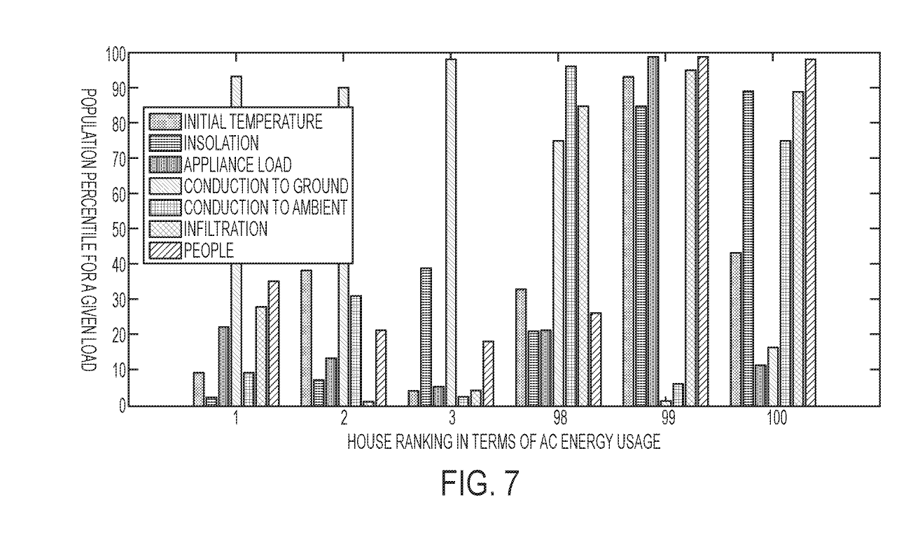

Another method of comparison is shown in FIG. 7, which shows the three lowest and three highest energy users. In FIG. 7 the houses are first ranked in terms of overall energy usage. The three lowest energy users (1-3) and the three highest energy users (98-100) are shown in this plot. For each house, the load for that house, compared on a percentile basis to the overall population is shown. The conduction to ground is a heat sink and thus a large bar here shows that the house has a means for cooling in addition to the AC.

A utility may choose to focus on energy outliers, those who consume an extraordinarily high amount of energy for AC compared to a population. These loads may be normalized before making the comparison. For each house, as is clear in this figure, the sources of the extraordinary demand differ.

For example, the utility can infer from this figure that the 98th house is likely an extraordinary energy user due to an extraordinary conduction load and extraordinary infiltration; the people loads and insolation loads are more typical of the population and are less likely to be the drivers of the extraordinary demand. These comparisons, like the comparisons within a house, are expected to be less-than-perfect but still accurate enough to have value for inferences across a population, for example for targeting energy efficiency rebates or outreach.

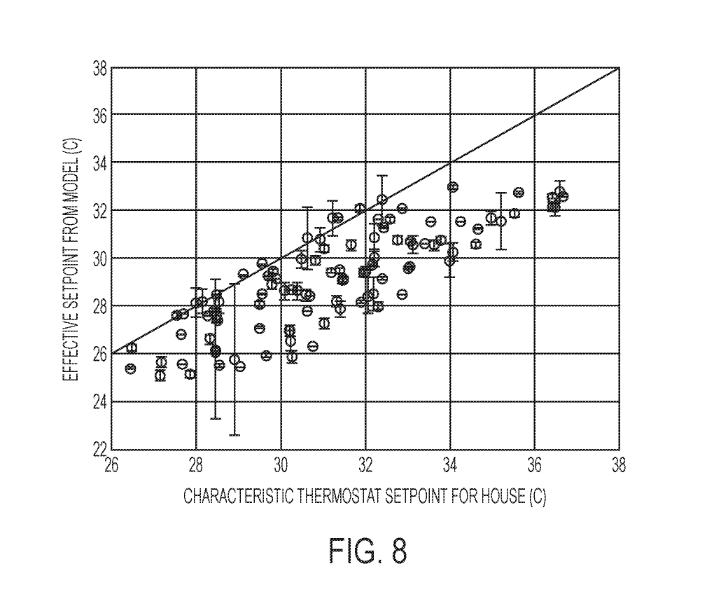

FIG. 8 is a plot that shows an output from the model, an effective setpoint, compared to an reported setpoint for a house. The effective setpoint does not exactly match the reported setpoint, however it is meaningful on a comparative basis. The error bars may be assessed from the quality of the model fit to the data for each house. They may also be measures of the importance of this parameter based on, for example, the significance of a given load for a given house.

The thermal load values determined by analysis of the model can be used to compare across a population metrics that are related to things that can actually be changed in a house in order to reduce energy consumption. The effective setpoint from the model can be compared house-to-house to understand which houses are most likely to have extraordinarily high or extraordinarily low setpoints, as illustrated in FIG. 8. This comparison can also consider the statistical quality of the model fit for this parameter; in this figure, this is illustrated by error bars. For houses where a fit parameter has a large error bar, this house might be excluded from the comparison due to uncertainty of information. The error bars may be a result of a statistical analysis of the quality of the model fit to this house or the uncertainty on the model fit for this parameter.

The importance or fidelity of a particular parameter might also be assessed by connecting the particular parameter as shown in FIG. 8 to a comparison of the loads as shown in the other figures, based on an understanding of the physics. If conduction load and infiltration load are a small amount of the total load for a house or small in comparison to other houses, the thermostat setpoint may be judged to be insignificant for a given house in the context of a population. The comparison of the thermal loads of the fit serve to point to specific things in a home that could be changed in order to reduce power consumption. One load, such as a conduction load to the outdoors, may be impacted by several factors, such as the thermostat setpoint and the quality of the insulation. To understand the things that a person can directly change in order to reduce consumption may require an understanding of multiple loads or an understanding of the factors associated with a load.

With this model used on a comparative basis across homes, an electric utility, for example, can understand which homes are most likely to have extraordinary thermostat setpoints and thus offer incentives or messaging around thermostat settings to a subset of the population based on this evaluation.

The model output can be used to guide communications between a utility or energy provider and households. This can be used for targeting energy efficiency (EE) or demand response (DR) programs so that these programs are offered first to the customers that most likely have technical opportunities to reduce their energy usage.

Such targeting could be enhanced by also including social demographic data or other data that might indicate which customers are most likely to be willing to make changes. This kind of targeting can increase the cost effectiveness of such utility programs, so that less resources are spent to achieve the same reductions in consumption. Similarly, the understanding from the model could be used to guide other communications, such as marketing of appliances, home improvement services or products, audits or other services related to understanding home energy consumptions, in which understanding the drivers of demand can help one party understand more clearly who might most benefit from certain services, offers, or products.

Some examples in this disclosure consider HVAC air conditioning (AC) the approaches disclosed herein can also be applied to heating, with appropriate changes in mathematical sign to account for the fact that a heating appliance generally is operated to compensate for heat loss from a house and an AC is typically operated to compensate for heat that is added to a house. Unlike an AC, a heater generally is tasked only with sensible heating, e.g., changing the temperature of the air in a house, while an air conditioner in cooling mode also may have a latent load as water may be removed from the air as it is cooled. In cold climates, there could be a system incorporated with or separate to the heater that controls humidity. There may also be separate systems for controlling the amount of outdoor air that is added to a home.

This approaches disclosed herein is particularly appropriate for standalone residential buildings. However, the disclosed approaches could be equally applied to other types of buildings such as apartments and other multi-family residential units or commercial buildings, with appropriate adjustments to the physics model.

The analyzer disclosed herein may be implemented as a processor or circuit configured to implement the processes outlined by the flow diagrams discussed herein. The detector and/or analyzer described herein may be implemented in hardware or by any combination of hardware, software and/or firmware. For example, in some embodiments, all or part of the analyzer may be implemented in hardware. In some embodiments, the analyzer may be implemented by a microcontroller implementing software instructions stored in a computer readable medium.

The foregoing description of various embodiments has been presented for the purposes of illustration and description and not limitation. The embodiments disclosed are not intended to be exhaustive or to limit the possible implementations to the embodiments disclosed. Many modifications and variations are possible in light of the above teaching.

1. A system comprising:
a detection interface configured to detect signals from which house data and environmental data for at least one house can be collected, the house data including at least power usage of the heating ventilation and air conditioning (HVAC) system of the house as a function of time;
an analyzer configured to compute values of thermal loads of the house based on the house data and the environmental data by solving a stochastic thermal energy balance equation for the house using thermal load estimates; and
an output interface configured to output information about the thermal loads of the house based on the computed thermal load values.

2. The system of claim 1, wherein the thermal load estimates are provided by maximum a posteriori probability estimation.

3. The system of claim 1, wherein the thermal load estimates are provided by maximum a priori probability estimation deduced by an expectation-maximization algorithm (EMMAP).

4. The system of claim 1, wherein the detection interface is further configured to detect non-HVAC appliance power usage data for appliances of the house as a function of time.

5. The system of claim 1, wherein the detection interface is configured to:
detect the household power usage data for the house; and
disaggregate the household power usage into HVAC system power usage data and appliance power usage data.

6. The system of claim 1, wherein the detection interface is configured to collect times that the HVAC system turns on and turns off from the signals and to determine power usage of the HVAC system from the collected on and off times.

7. The system of claim 1, wherein the detection interface is configured to sense current or fuel drawn by the HVAC system.

8. The system of claim 1, wherein the environmental data has a time resolution that is different from a time resolution of the power usage of the HVAC system.

9. The system of claim 1, wherein the analyzer is configured to solve a thermal energy balance equation for sets of consecutive active cycles of the HVAC system.

10. The system of claim 1, wherein the output information comprises a comparison of the thermal loads of the house.

11. The system of claim 1, wherein the output information comprises a ranking of relative importance of each of the thermal loads with respect to increasing energy efficiency.

12. The system of claim 1, wherein:
the at least one house comprises a population of houses;
the detection interface is configured to collect house data and environmental data for the population of houses; and
the analyzer is configured to determine, for each house, contributions to the total energy usage of the house for each thermal load of the house and to compare the thermal load contributions across the population of houses.

13. A computer implemented method comprising:
detecting signals from which house data and environmental data for at least one house can be collected;
collecting the house data including at least power usage of the heating ventilation and air conditioning (HVAC) system of the house as a function of time;
collecting the environmental data for the house, the house data and environmental data comprising inputs to a physics model of the house, the physics model including a stochastic thermal energy balance equation for the house;
computing values of thermal loads of the house based on the house data and the environmental data by solving the stochastic thermal energy balance equation using thermal load estimates; and
outputting information about the thermal loads of the house based on the calculated thermal load values.

14. The method of claim 13, wherein the thermal load estimates are provided by maximum a posteriori probability estimation deduced by an expectation-maximization algorithm (EMMAP).

15. The method of claim 13, wherein:
the house data further includes one or more of:
physical configuration of the house;
coefficient of performance (COP) of the HVAC system;
efficiency of the HVAC system;
number of setpoints of the HVAC system; and
power use data for appliances of the house as a function of time; and
the environmental data includes one or more of:
air temperature;
ground temperature beneath the house;
humidity;
wind;
cloud cover;
visibility; and
solar radiation.

16. The method of claim 13, wherein collecting the HVAC system power usage comprises detecting the household power usage for the house and disaggregating the household power usage into HVAC system power usage and non-HVAC appliance power usage.

17. The method of claim 13, wherein collecting the HVAC system power usage comprises at least one of:
detecting times that the HVAC system turns on and turns off;
sensing current drawn by the HVAC system;
sensing fuel drawn by the HVAC system; and
receiving information associated with the HVAC system power usage from a networked thermostat.

18. The method of claim 13, wherein the physics model comprises one or more thermal masses and thermal conductances that connect the thermal masses with each other, with ambient air, and with ground.

19. The method of claim 18, wherein the one or more thermal masses include a first thermal mass that represents thermal mass of circulating air in the house and a second thermal mass that represents thermal mass of house structures including one or more of roof, walls, and floor of the house.

20. The method of claim 13, wherein the physics model includes a random variable to take into account random errors in the house data and/or the environmental data.

21. The method of claim 13, wherein the thermal loads comprise at least two of:
initial temperature load;
insolation load;
appliance load;
thermal conduction to ground load;
thermal conduction to ambient air load;
infiltration load; and
people load.

22. The method of claim 13, wherein:
calculating the values of the thermal loads of the house comprises calculating a fractional contribution of each thermal load to a total thermal load of the house; and
outputting the information comprises outputting the fractional contribution of each thermal load to the total thermal load.

23. The method of claim 13, further comprising:
ranking a relative importance of each of the thermal loads with respect to increasing energy efficiency based on the thermal load values; and
outputting the ranking of the relative importance for each of the thermal loads.

24. The method of claim 13, wherein:
the at least one house comprises a population of houses;
further comprising:
determining for each house, a proportion of the total energy usage of the house associated with each thermal load of the house; and
comparing the proportions of the total energy usage associated with the thermal loads across the population of houses.

25. A system comprising:
a detection interface configured to detect signals from which house data and environmental data for at least one house can be collected, the house data including at least power usage of the heating ventilation and air conditioning (HVAC) system of the house as a function of time;
an analyzer configured to compute values of thermal loads of the house based on the house data and the environmental data by solving a stochastic thermal energy balance equation for the house using thermal load estimates; and
an output interface configured to:
output information about the thermal loads of the house based on the computed thermal load values; and
output at least one control signal that alters one or more aspects of the house in response to the calculation of the thermal load values.

26. The system of claim 25, wherein the control signal is configured to lower or raise window coverings, increase or decrease ventilation, turn appliances on or off, and/or alter the operation of the HVAC system.
